(19) United States
(12) Patent Application Publication
(10) Pub. No.: US 2026/0162876 A1
(43) Pub. Date: Jun. 11, 2026

(54) COIL BOARD, AND METHOD FOR PRODUCING A COIL BOARD

(71) Applicant: Turck Holding GmbH, Halver (DE)

(72) Inventor: Michael Faber, Altena (DE)

(73) Assignee: Turck Holding GmbH, Halver (DE)

(21) Appl. No.: 19/408,394

(22) Filed: Dec. 4, 2025

(30) Foreign Application Priority Data
Dec. 5, 2024 (DE) 10 2024 136 312.6

(51) Int. Cl. H01F 27/28; H01F 27/32; H01F 38/14; H01F 41/04; H01F 41/12

(52) U.S. Cl. CPC H01F 27/2804; H01F 27/2871; H01F 27/288; H01F 27/323; H01F 38/14; H01F 41/041; H01F 41/122; H01F 2027/2809

(57) ABSTRACT

A coil board (101), optionally for an inductive proximity switch, optionally for flush mounting in a metallic environment, comprises at least one coil element (102), and a recess (103) in the coil board (101) that is formed in an encircling and closed manner around the coil element (102), and a shielding element (104), wherein the shielding element (104) is arranged in the recess (103) of the coil board (101).

### CROSS REFERENCE TO RELATED APPLICATION

This application claims priority to German patent application 10 2024 136 312.6 filed on Dec. 5, 2024, which is hereby incorporated by reference in its entirety.

### TECHNICAL FIELD

The present disclosure relates to a coil board, optionally for an inductive proximity switch, optionally for flush mounting in a metallic environment. The disclosure relates further to a method for producing the disclosed device, optionally an inductive proximity switch. Furthermore, the disclosure relates to the use of the disclosed device in an inductive proximity switch.

### BACKGROUND

Inductive proximity switches are used in a large number of industrial applications in order to detect the presence or movement of metallic objects. These sensors typically work by generating and evaluating electromagnetic fields, which are generated by a coil on a printed circuit board.

Two main designs of such sensors are known: flush proximity sensors and proximity sensors that cannot be flush mounted. In the case of non-flush sensors, it is necessary for a distance to be maintained around the coil relative to metallic environments in order to prevent impairment of the sensor function. In the case of flush sensors, the coil is positioned directly on the front side of the sensor housing, which allows the sensor to be integrated in metallic environments without the need for a distance. This can be important when the sensor is to be integrated in a metallic environment, for example in machine components or base plates.

In order to shield the electromagnetic coil from external interference by the metallic environment, a shielding is frequently used. In the prior art, shielding elements are either attached directly around the coil or are fixed using additional materials such as potting compounds. However, these solutions have disadvantages when it comes to positioning and fixing the shielding exactly.

DE 10 2021 114 948 A1 discloses a proximity sensor for the inductive detection of objects. The sensor comprises a housing having a front cap, which forms the detection side of the sensor. A processing and receiving unit, which contains a printed circuit board, is able to be connected to an external control and/or evaluation unit. At least one primary coil and at least one first secondary coil are arranged, spaced apart in the axial direction, on a single- or multi-part coil carrier, wherein the coils are either wound or printed. The end face of the coil carrier lies directly opposite the inner surface of the front cap or abuts against said surface. The secondary coil is arranged closer, in the axial direction, to the end face than the primary coil. A metallic shielding element is arranged in the axial region of the second secondary coil and around said coil, while a metallic shielding element is not provided in the axial region of the first secondary coil.

One possible disadvantage of this prior art can be that the shielding of coils in inductive proximity sensors is often positioned inaccurately and can require additional working steps such as potting or adhesive bonding of the shielding element. This procedure can make the manufacturing process more difficult and leads to increased production costs and inaccurate shielding effects. Moreover, incorrect positioning of the shielding element can impair the range and sensitivity of the sensor.

### SUMMARY

A coil board is provided, the coil board comprising an insulating carrier material, at least one coil element formed on top of or at least partly inside the insulating carrier material, a recess that is formed in an encircling and closed manner around the coil element, wherein the recess is embedded in the insulating carrier material, and a separate, preformed shielding element, wherein the shielding element is arranged precision-fitted in the recess of the coil board.

### BRIEF DESCRIPTION OF THE DRAWINGS

In the drawings:

FIG. 1 shows a schematic representation of a first exemplary, non-limiting implementation of the coil board;

FIG. 2 shows a schematic representation of the first exemplary, non-limiting implementation without a shielding element;

FIG. 3 shows a schematic representation of the second exemplary, non-limiting implementation of the coil board;

FIG. 4 shows a schematic representation of the third exemplary, non-limiting implementation of the coil board;

FIG. 5 shows a schematic representation of the fourth exemplary, non-limiting implementation of the coil board;

FIG. 6 shows a schematic representation of an individual layer of the first exemplary, non-limiting implementation of the coil board with section axis A;

FIG. 7 shows a schematic representation of a cross section of the first exemplary, non-limiting implementation of the coil board;

FIG. 8 shows a flow diagram of a method according to the disclosure.

### DESCRIPTION

In the following, details are set forth to provide a more thorough explanation of the disclosure. However, it will be apparent to those skilled in the art that these implementations may be practiced without these specific details. In other instances, well-known structures and devices are shown in block diagram form or in a schematic view rather than in detail to avoid obscuring the disclosure. In addition, features described hereinafter may be combined with each other, even if described with respect to different figures, unless specifically noted otherwise.

Equivalent or like elements or elements with equivalent or like functionality are denoted in the following description with equivalent or like reference numerals. As the same or functionally equivalent elements are given the equivalent or like reference numbers in the figures, a repeated description for elements provided with the equivalent or like reference numbers may be omitted. Hence, descriptions provided for elements having the equivalent or like reference numbers are mutually exchangeable.

Directional terminology, such as “top,” “bottom,” “below,” “above,” “front,” “behind,” “back,” “leading,” “trailing,” etc., may be used with reference to the orientation of the figures being described. Because parts of the disclosure, described herein, can be positioned in a number of different orientations, the directional terminology is used for purposes of illustration and is in no way limiting. It is to be understood that other implementations may be utilized, and structural or logical changes may be made without departing from the scope defined by the claims. The following detailed description, therefore, is not to be taken in a limiting sense.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In implementations described herein or shown in the drawings, any direct electrical connection or coupling, e.g., any connection or coupling without additional intervening elements, may also be implemented by an indirect connection or coupling, e.g., a connection or coupling with one or more additional intervening elements, or vice versa, as long as the general purpose of the connection or coupling, for example, to transmit a certain kind of signal or to transmit a certain kind of information, is essentially maintained. Features from different implementations may be combined to form further implementations. For example, variations or modifications described with respect to one of the implementations may also be applicable to other implementations unless noted to the contrary.

The terms “substantially” and “approximately” may be used herein to account for small manufacturing tolerances (e.g., within 5%) that are deemed acceptable in the industry without departing from the aspects of the implementations described herein. For example, a resistor with an approximate resistance value may practically have a resistance within 5% of that approximate resistance value.

In the present disclosure, expressions including ordinal numbers, such as “first”, “second”, and/or the like, may modify various elements. However, such elements are not limited by the above expressions. For example, the above expressions do not limit the sequence and/or importance of the elements. The above expressions are used merely for the purpose of distinguishing an element from the other elements. For example, a first box and a second box indicate different boxes, although both are boxes. For further example, a first element could be termed a second element, and similarly, a second element could also be termed a first element without departing from the scope of the present disclosure.

Optionally, a solution can be provided which ensures exact positioning and fixing of a shielding element and at the same time simplifies and optimizes the manufacturing process. Optionally, the sensitivity and range of the sensor can be optimized by an improved shielding effect, while the production costs may be lowered.

A coil board, optionally an inductive proximity switch, optionally for flush mounting in a metallic environment, is provided. The coil board comprises at least one coil element. The coil board further has an encircling and closed recess around the coil element. It is further provided that a shielding element is arranged in the recess of the coil board.

This feature can have the technical effect of effectively shielding the coil from electromagnetic interference. This can lead to improved sensitivity and stability of the sensor, since the shielding is positioned precisely and stably in the recess, so that the performance of the sensor is increased.

Within the context of this disclosure, an inductive proximity switch can be understood as being a contactless sensor based on the generation and detection of electromagnetic fields. Such switches detect the approach of metallic objects and initiate a switching function without the need for direct contact. At least one transmitting and/or receiving coil is provided and is responsible for generating or detecting the electromagnetic field. The technical effect of these switches is that they permit reliable detection in industrial applications where mechanical actuation is not feasible.

Within the context of this disclosure, a coil board can be understood as being a printed circuit board that serves especially for the integration of coil elements. The coil is not wound as a separate component but is integrated in the track structure of the board, which permits a more compact construction and higher efficiency. The coil, for example the coil element in the form of a receiving and/or transmitting coil, can be a planar coil, optionally a printed coil. In addition, the coil board can contain additional electronic components, which are formed on the board, as well as corresponding electrical connections, which allow the board to be used as a full-featured electronic switching module. These additional components can comprise, for example, signal processing components, amplifiers or connection points, in order to ensure the functionality of the coil board in larger electronic systems. This makes the coil board a complete module, which is ready for use, optionally in sensor technology.

Within the context of this disclosure, flush mounting in a metallic environment can be understood as meaning an installation in which the sensor, optionally at least one coil element of the sensor, is flush with the surface of the metallic environment, which can mean with the metallic surface or the edge of a metallic housing opening of the machine or system, such as, for example, a gate system, whereby a compact and mechanically protected construction is achieved. Flush mounting can further involve the coil element of the sensor being surrounded at least partially by metallic materials.

By contrast, in the case of the non-flush mounting of a sensor, for example of an inductive proximity switch, a clearance is provided around the active surface. In this case, it can be provided that a non-flush mounted sensor protrudes a little further from the metallic environment, optionally such that the coils are not surrounded by the metallic material.

The coil board can be arranged in an at least partially metallic housing or in a non-metallic housing. In the case of non-flush mounting, the sensor can project from the surface of the mounting environment, optionally the metallic mounting environment; in the case of flush mounting, it is flush with the (metallic) mounting environment.

Within the context of this disclosure, a coil element can be understood as being a structure that consists of multiple windings of a conductive material, such as copper. The coil element can be in the form of a planar coil, optionally a printed coil. The coil element serves to generate an electromagnetic field, which is used for the functioning of a sensor, for example an inductive proximity switch. The coil element is integrated on the coil board and can be distributed over multiple layers of the board. The at least one coil element can comprise, inter alia, at least one transmitting coil and/or one receiving coil. The coil element can be of polygonal form. The at least one receiving coil and the at least one transmitting coil can optionally be in the form of a printed coil. They can further be arranged in layers one above the other.

The coil system has a coil board on which there are arranged at least one first receiving coil and one transmitting coil. The first receiving coil comprises a coil that is of polygonal form.

Within the context of this disclosure, a recess can be understood as being an encircling and closed depression in the coil board, which is produced, for example, by milling or depth milling. This depression can surround the coil element completely in the manner of a castle moat, so that the coil element is surrounded like an island. The recess runs, for example, continuously and without interruption around the coil element, so that a closed, annular, optionally circular or polygonal, depression is formed. This design allows the shielding element to be fitted precisely into the milled recess, which ensures optimal shielding of the coil element with respect to electromagnetic interference. In addition, it permits a novel joining technique and method, for example when inserting the shielding element into the recess, or when populating the coil board.

It can additionally be provided that the shielding element is arranged parallel to at least one layer of the coil board. Within the context of this disclosure, parallel to at least one coil layer can mean that the shielding element is arranged in the recess such that, owing to the encircling and closed configuration of the recess around the coil element, the recess has the form of a moat. The recess runs through the multi-layer structure of the coil board. The shielding element is so arranged that it lies in a plane, which can correspond to at least one of these layers of the coil board. Depending on the thickness of the shielding element and the depth of the recess, the shielding element can be oriented parallel to multiple layers of the coil board, i.e. it can extend over multiple layers of the coil board, whereby it makes possible precise shielding over the entire coil board.

The shielding element accordingly ensures electromagnetic shielding that is matched directly to the coil element, so that the effectiveness of the electromagnetic shielding of the coil board is optimized and maximized.

Within the context of this disclosure, a shielding element can be understood as being a conductive component that is arranged in the recess of the coil board. It serves to block or reduce electromagnetic interference from outside and to preserve the electromagnetic integrity of the coil element. The shielding element can consist of a conductive material, such as CuZn alloys, for example brass (CuZn), or copper (Cu) and ensures that the coil element works without problems.

The conductive material of the shielding element has the technical effect that it offers high electromagnetic conductivity and thus efficiently reduces electromagnetic interference. This improves the stability and functionality of the sensor by minimizing external interference.

Within the context of this disclosure, a conductive material can be understood as being a material that has high electrical conductivity and is used especially for shielding electromagnetic fields. Typical materials comprise copper (Cu), which is particularly suitable owing to its high conductivity, as well as brass (CuZn), which likewise offers excellent shielding properties. The technical effect of these materials consists in that they permit the efficient blocking of electromagnetic interference, whereby the performance of the device is increased.

It can further be provided that the shielding element is arranged as a separate component in the recess of the coil board.

The shielding element as a separate component has the technical effect that it can be manufactured independently of the coil board and inserted precisely into the recess. This facilitates assembly and allows materials and components to be selected more flexibly in order to meet specific requirements.

Within the context of this disclosure, a separate component can be understood as being an independent structural element that is not permanently integrated in the coil board but is inserted retrospectively into the recess. This permits flexible manufacture of the shielding element, which in turn has the technical effect that different shielding elements for different applications are easily exchangeable without the entire coil board having to be produced again.

It can further be provided that the shielding element has a closed form. This closed form can be annular, for example.

Within the context of this disclosure, a closed form can be understood as being a continuous geometric structure that encloses the coil element completely. This closed form can be annular, for example.

Within the context of the present disclosure, annular can include both a circular form and a polygonal, for example rectangular or square, form.

Within the context of the present disclosure, a square form with rounded corners is also considered to be annular, since it fulfils the function of an encircling shielding element. The technical advantage of this form lies in the improved mechanical integration in the recess of the board, whereby the loads on mounting are reduced and the positioning of the shielding element is more stable.

The shielding element of closed form further has the technical effect that it offers uniform and complete shielding around the coil element. This results in an improved shielding effect, since electromagnetic interference can be blocked from all directions. The closed path of the shielding element allows an electric current to be induced therein, which contributes toward reducing undesirable electromagnetic fields. This has the effect that the coil element works more stably because interference fields are absorbed and dissipated. The closed path thus forms a barrier, which encloses the electromagnetic field of the coil element and protects it from external influences.

Owing to these properties, the shielding element can be designed as a short-circuit ring. A short-circuit ring offers the additional advantage that, as a result of the induced current, it actively dampens the electromagnetic field of the coil and effectively shields undesirable interference.

It can further be provided that the recess and the shielding element have the same closed form, so that the form of the shielding element corresponds to the form of the recess. The technical advantage of this form lies in the improved mechanical integration in the recess of the coil board, whereby the loads on mounting of the shielding element are reduced and the positioning of the shielding element is more stable.

It can further be provided that the shielding element is circular. Within the context of this disclosure, the term circular can include forms that are elliptical, approximately circular or exactly circular.

It can also be provided that the shielding element is polygonal.

Within the context of this disclosure, the term polygonal can include a form with straight sides and multiple corners, such as, for example, a triangle, quadrilateral, hexagon or other polygons. The term includes both symmetrical and asymmetrical polygons.

It can further be provided that the shielding element is polygonal with rounded corners, The technical effect of these rounded corners consists in that they permit better accuracy of fit on insertion of the shielding element into the recess of the coil board. The rounded corners facilitate population of the board and reduce the risk of mechanical stresses or inaccuracies of fit during assembly.

It can further be provided that the coil element is formed in at least one layer of the coil board. It can further be provided that the shielding element is arranged in at least that layer of the coil board.

The coil element in one or more layers of the coil board has the technical effect that the sensitivity and electromagnetic power of the sensor, for example an inductive proximity switch, is improved, while the space requirement continues to be minimized. The possibility of integrating the shielding element in the same layer of the coil board permits precise matching between the shielding and the coil element, which further increases the efficiency of the shielding and at the same time keeps the construction of the board compact.

Within the context of this disclosure, the expression—in at least one layer of the coil board—can be understood as meaning an arrangement in which the coil element is integrated in one or more layers of the coil board. This configuration optimizes the electromagnetic properties of the coil element, since the use of one or more layers permits a higher inductance without increasing the space requirement. In addition, the shielding element can be placed in the same layer as the coil element, whereby exact positioning and matching of the shielding relative to the coil element is achieved without causing additional installation space requirements.

As a result of the arrangement of the shielding element in at least one layer of the coil board, the electromagnetic shielding is integrated directly in the structure of the coil board. The shielding effect is thus enhanced without increasing the installation space, which makes the overall construction of the sensor more compact and more efficient.

It can further be provided that the areal extent of the coil element can correspond to 70-90% of the areal extent of the shielding element. Optionally, the ratio can be 75-85%, optionally 77-82%, optionally 80%.

Within the context of this disclosure, the expression areal extent of the coil element in relation to the areal extent of the shielding element can be understood as meaning the ratio of the projected area of the coil element to the area of the shielding element. The areal extent of the coil element can be 70-90% of the areal extent of the shielding element, wherein 75-85%, optionally 77-82%, optionally 80%, is regarded as being particularly advantageous.

The specific ratio between the areal extent of the coil element and that of the shielding element has the technical effect that the shielding is optimally matched to the electromagnetic field strength of the coil element. This leads to an efficient reduction of electromagnetic interference without impairing the sensor sensitivity. The indicated size ratio ensures that the shielding element encloses the coil element in the best possible manner, which leads to an improved performance of the sensor, optionally in the case of the reduction of interference at the edges.

The areal extent can refer to the geometric area occupied by both the coil element and the shielding element on a common plane. This areal extent not only takes account of the diameter (in the case of circular or annular structures) but describes the entire 2D area occupied by the coil element and the shielding element on the coil board, irrespective of their form (e.g. circular, polygonal).

The technical effect of this dimensioning is that the electromagnetic shielding optimally encloses the coil element and maximizes the efficiency of the shielding. As a result of the precise size ratio, the electromagnetic field of the coil element is purposively shielded without impairing the sensor sensitivity. Optionally in the preferred size ratios of 75-85% or 77-82%, more precise control of the electromagnetic field distribution is achieved, whereby the shielding effect is improved and the electromagnetic efficiency is optimized.

Furthermore, the coil board can be configured such that sensors having a size of 40×40 mm, for example inductive proximity switches, are formed. The recess can be configured such that it is able to accommodate the shielding element with a cross section of 0.8×0.8 mm. The maximum sensitivity or range can thus be obtained optionally in the center and can lead to less sensitivity at the edge of the coil board.

The method for producing a coil board within the context of the disclosure comprises the following steps: providing a coil board comprising at least one coil element, forming a recess in the coil board, wherein the recess is formed in an encircling and closed manner around the coil element, and arranging a shielding element in the recess of the coil board.

The method is suitable optionally for producing the coil board described herein. It therefore has the corresponding advantages and can be developed analogously to the coil board.

The production method has the technical effect that the device can be produced efficiently by precise introduction of the shielding element into the recess of the coil board. The arrangement of the shielding element in the recess increases the electromagnetic shielding effect and improves the functionality of the sensor, optionally inductive proximity switch. Moreover, the more accurate placing permits a compact construction and higher production accuracy.

Within the context of this disclosure, the term providing can be understood as meaning the step in the production process in which the required components, optionally the coil board and the coil element, are prepared and made available for assembly. The technical effect of this step is that a clean starting basis for the subsequent processing steps is created.

The term forming the recess refers within the context of this disclosure to the process in which an encircling and closed depression is created in the coil board by milling or depth milling, in order to accommodate the shielding element. The technical effect consists at least in that a precise and uniform holder for the shielding element is formed, which improves the shielding performance of the sensor.

Within the context of this disclosure, the expression arranging the shielding element can be understood as meaning the process in which the shielding element, which can be formed of an electrically conductive material, is inserted into the previously formed recess. The shielding element that is positioned in the recess has the technical effect that the electromagnetic shielding is matched directly to the coil element, whereby the effectiveness of the shielding is maximized.

It can further be provided that the method, within the context of the disclosure, further comprises fixing the shielding element in the recess, optionally by soldering.

Within the context of this disclosure, the expression fixing the shielding element can be understood as meaning the process in which the shielding element is fastened in the recess of the coil board. This can be carried out by various methods of mechanical fastening, for example soldering and/or adhesive bonding.

Fixing of the shielding element in the recess, optionally by soldering, has the technical effect that a stable mechanical and electrical connection between the coil board and the shielding element is produced, which ensures the electromagnetic shielding effect over the long term. This stable connection reduces the risk of movement or displacement of the shielding element during operation, which increases the long-term stability and reliability of the sensor.

In the context of this disclosure, the term soldering describes a method in which the shielding element is permanently fixed in the recess by a soldered connection. The technical effect of soldering consists in that a mechanically stable connection between the coil board and the shielding element is created, which ensures reliable shielding and long-term mechanical stability.

For example, soldering can be carried out by placing one or more solder areas (solder pads) at the edge of the coil board. The shielding element can thus be soldered in places.

It can further be provided that the device within the context of the present disclosure is used in an inductive proximity switch for flush mounting in a metallic environment.

The use of the device in an inductive proximity switch for flush mounting in a metallic environment has the technical effect that the sensor can be integrated in a metallic mounting environment seamlessly and without protruding parts. This allows a compact construction which protects the sensor from mechanical damage and at the same time ensures precise detection of metallic objects. Inductive proximity switches detect the approach of metallic objects and initiate a switching function without the need for direct contact. The technical effect of these switches is that they permit reliable detection in industrial applications where mechanical actuation is not feasible.

What has been described above can be summarized in other words to a possible configuration of the disclosure as described below, wherein the following description is not to be interpreted as being limiting for the disclosure.

Coils are part of inductive proximity switches and are used for transmitting and evaluating electromagnetic fields. Coils can be configured both with copper wire in wound form or, in printed circuit board technology, with printed copper tracks. There are two different forms of inductive proximity switches, for flush mounting in metal and for non-flush mounting with a metal-free zone around the sensor coil.

A flush coil system according to the present disclosure is to be provided, said system enabling all requirements of flush mounting in a metallic environment and optionally allowing a solution that, as regards the internal construction and the manufacture of the sensor, is optimized in terms of production costs. As a result of the solution, in which a shielding element, for example a short-circuit ring, is positioned and fixed in a recess, for example a depth-milled region, of a coil in printed circuit board technology, all requirements made of a flush sensor for cost-optimized manufacture have been met.

Within the context of this description, a coil system can comprise one or more coils, which are integrated on a coil board, as well as further components, which serve for signal processing and shielding. The coil system comprises at least one receiving coil and/or at least one transmitting coil. In addition, the coil system comprises not only the coils or coil elements themselves, but also necessary supply lines for associated electronics, in order to permit precise detection and processing of electromagnetic fields. Such systems are important optionally in sensors in order to ensure stable and exact measured values.

In order that inductive sensors can be flush mounted, the coils in such sensors must be shielded internally in the sensor with respect to the metallic mounting and construction environment of the sensor by a conducting shielding. This is ensured by a shielding element, for example a shielding ring and/or short-circuit ring, of CuZn or Cu around the coil. This shielding is usually a closed ring, which is placed around the coil/coil board in a front cap. A disadvantage of this solution is that, with the insertion of the ring, the shielding element is not permanently connected and positioned in the front cap. This is not performed until later in the manufacturing sequence by an additional working step, for example filling of the front cap with a potting resin or fixing of the shielding element by adhesive bonding or plastics overmolding.

In the prior art, either a standard shielding, for example a shielding ring, is placed around the coil and fixed with potting compound or, in the case of printed coil boards, shielding can take place by edge plating.

A disadvantage of the design in the prior art with a standard shielding such as shielding rings is the problem that permanent positioning does not take place prior to potting, so that transport and handling of the non-potted assembly groups in the ongoing manufacturing process is difficult. In the case of edge plating, the small copper thickness is a disadvantage and does not offer the same good shielding effect for flushness as a solid Cu or CuZn ring.

According to the present disclosure, a new construction of the coil board with a shielding element, optionally a shielding ring, is implemented. A depth-milled region or recess is here introduced into the coil board in the direction of the active sensor surface (front cap base), and the shielding element is inserted into said recess and thus permanently positioned. Permanent positioning of the shielding element with respect to the coil element or the coil board can take place. In a manufacturing process, the coil board can be filled with a potting compound so that final fixing of the shielding element in the recess can thus be ensured. This positioning of the shielding element achieves an optimal shielding effect on the coil system and does not require a further manufacturing step for fixing in the front cap.

One design according to the present disclosure is a single-board design, in which the coil system and the switch are placed on one board. The shielding element, for example in the form of a short-circuit ring, is optionally of square form and is inserted into the depth-milled region parallel to the front copper layers, in which the coil system is laid out.

A further design according to the present disclosure provides that the coil board and the electronics board are separate. The short-circuit ring is here of round form and positioned with the maximum diameter in a depth-milled region for shielding.

In addition, the designs according to the present disclosure are possible as a coil board, as a design with a complete sensor board, coil system including electronics board, as designs for sensors in plastics housings for internal shielding in the case of flush sensors and as designs for sensors in cylindrical metal housings, in order to be able to produce more inexpensively as a result of the simplified possibilities of the joining technique on assembly of the assembly groups.

Advantages over the previous prior art are shielding of the coil by the shielding element (for example short-circuit ring) only in the height of the coil system and thus optimal utilization of the maximum spread of the electromagnetic field. Very high switching distances can thus be achieved. By positioning the shielding element (for example short-circuit ring) in the recess (depth-milled region) of the coil board, direct positioning and fixing is possible on assembly of the device. The disclosure enables novel joining techniques and methods, such as, for example, installation of the shielding element during population of the board, fixing of the shielding element (short-circuit ring) by soldering, after positioning in the front cap of the sensor.

The above exemplary, non-limiting implementations and developments can be combined with one another as desired, where expedient. Further possible exemplary, non-limiting implementations, developments and implementations of the disclosure also include combinations that have not explicitly been mentioned of described above or in the following in respect of features of the disclosure. Optionally, a person skilled in the art will also add individual aspects as an improvement of or additions to the respective basic form of the present disclosure. Optionally, features of the device claims can be implemented and/or performed by corresponding functions, so that these supplement or expand the method.

Furthermore, method steps can be implemented by corresponding implementation modules in the device. Accordingly, what has been described above in relation to the device also applies analogously to the method and vice versa.

The accompanying drawings are intended to provide a further understanding of the development of the disclosure. They illustrate developments and, in association with the description, serve to explain principles and concepts of the disclosure. Other developments and many of the mentioned advantages will become apparent from the drawings. The elements of the drawings are not necessarily shown true to scale relative to one another.

In the FIGS., elements, features and components that are identical, functionally identical and/or have the same effect are in each case provided with the same reference signs—unless indicated otherwise.

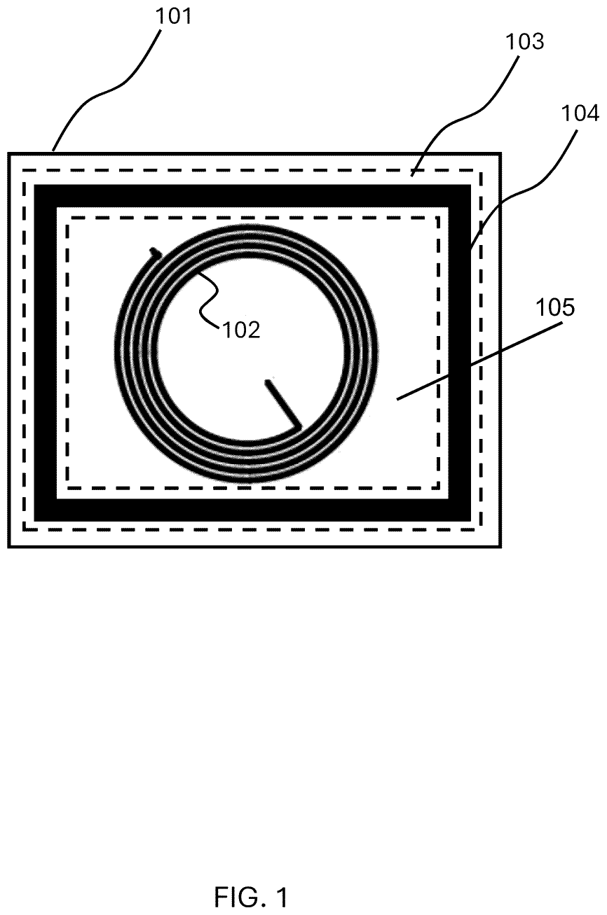

FIG. 1 shows a schematic representation of the first exemplary, non-limiting implementation of the coil board 101.

The coil board 101 comprises an insulating carrier material 105, at least one coil element 102 formed on top of or at least partly inside the insulating carrier material 105, a recess 103 that is formed in an encircling and closed manner around the coil element 102, wherein the recess 103 is embedded in the insulating carrier material 105, and a separate, preformed shielding element 104, wherein the shielding element 104 is arranged precision-fitted in the recess 103 of the coil board 101.

More specifically, the coil board 101 is shown with the coil element 102.

The coil element 102 can function, for example, as a receiving or transmitting coil.

In all the examples of the FIGS. in the description, the coil element 102 can be in the form of a receiving or transmitting coil.

The coil element 102 is circular and spiral-shaped.

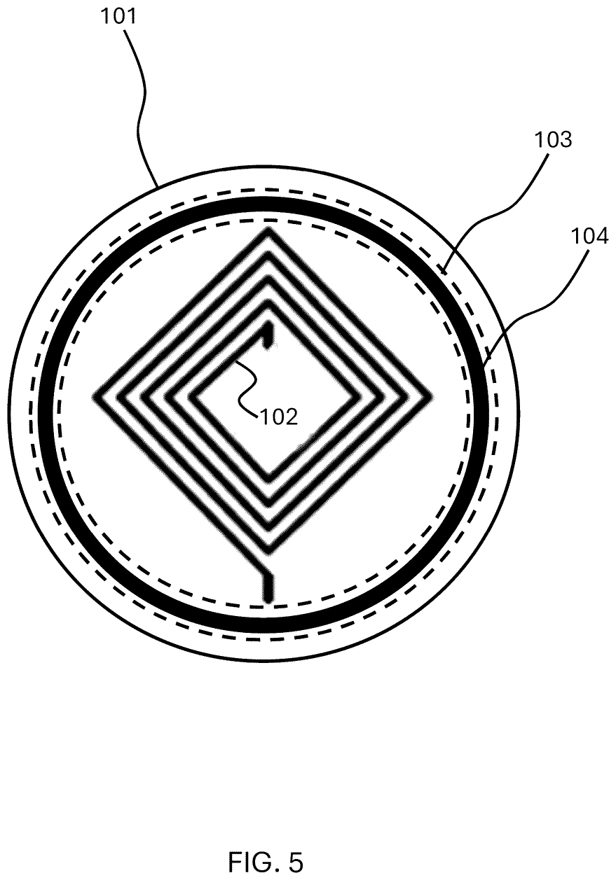

The coil element 102 can also form other spiral shapes. For example, in FIG. 5 a diamond-shaped coil element 102 is shown. Other polygonal forms are also possible.

The coil element 102 can assume any desired form, as long as it is arranged within the recess 103 and the shielding element 104.

In this exemplary, non-limiting implementation, the coil element 102 is in the form of a planar coil.

In a further exemplary, non-limiting implementation (not shown), the coil element 102 can be in the form of a printed coil.

An encircling and closed recess 103 has been formed in the coil board 101 around the coil element 102.

The recess 103 can be formed by milling or depth milling, for example.

The shielding element 104 is positioned in the recess 103 and serves for the electromagnetic shielding of the coil element 102.

In this exemplary, non-limiting implementation, the recess 103 forms a square annular region around the coil element 102.

The shielding element 104 is formed according to the recess 103. Optionally, the shielding element 104 is likewise closed and encircling, like a square ring.

The shielding element 104 forms a short-circuit ring, for example, and serves for the electromagnetic shielding of the coil element 102. This applies for all exemplary, non-limiting implementations of the description.

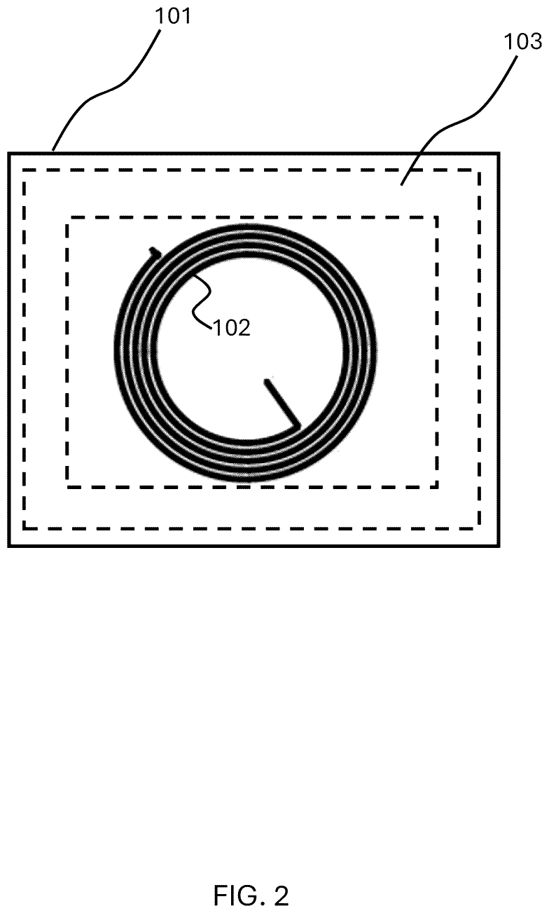

FIG. 2 shows a further exemplary, non-limiting implementation. In the schematic representation of FIG. 2, the first exemplary, non-limiting implementation is shown without a shielding element 104.

The coil board 101 without the shielding element 104 shows the closed encircling recess 103.

The encircling and closed recess 103 is arranged in the coil board 101 around the coil element 102. The recess 103 forms a kind of moat around the coil element 102. The recess 103 of this exemplary, non-limiting implementation, and generally of all exemplary, non-limiting implementations of the description, permit a novel joining technique/method, such as, for example, installation of the shielding element 104 during population of the coil board 101.

The coil element 102 is designed, for example, as a printed planar coil and is circular, optionally spiral-shaped.

The recess 103 surrounds the coil element 102 completely and is configured to accommodate the shielding element 104.

The recess 103 specifies the form of the shielding element 104, or of the short-circuit ring, since the shielding element 104 is arranged in the recess 103.

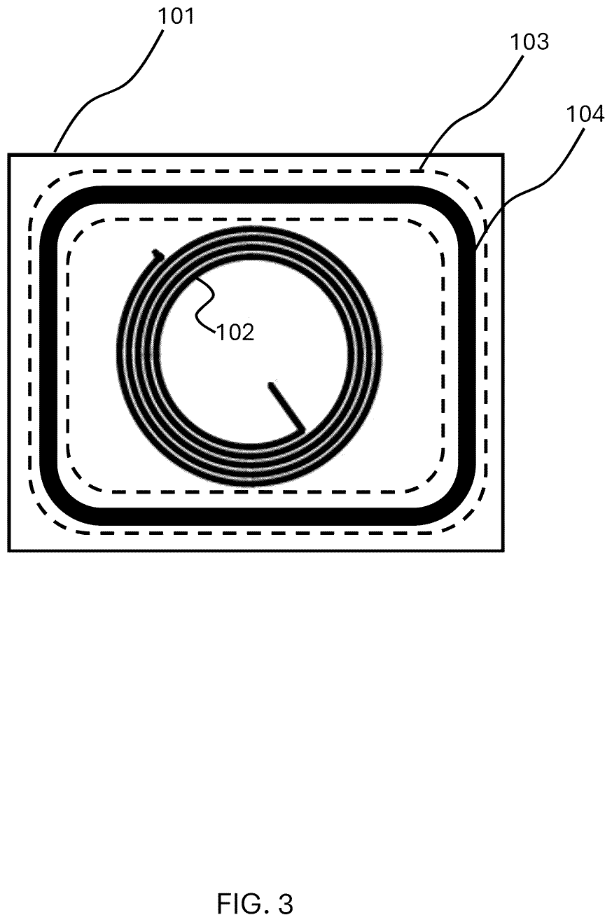

FIG. 3 shows a further exemplary, non-limiting implementation with a schematic representation of the second exemplary, non-limiting implementation of the coil board 101.

The coil element 102 is again circular and spiral-shaped.

The coil element 102 is a planar coil and can also be in the form of a printed coil, for example.

An encircling recess 103 surrounds the coil element 102, wherein the shielding element 104 is arranged in the recess 103 in order to ensure uniform electromagnetic shielding.

The recess 103 and the shielding element 104 are designed with rounded corners.

The rounded corners of the recess 103 and of the shielding element 104 provide a more precise accuracy of fit in the coil board 101. The rounded corners reduce the risk of mechanical stresses or inaccuracies of fit during assembly and facilitate the insertion of the shielding element into the recess.

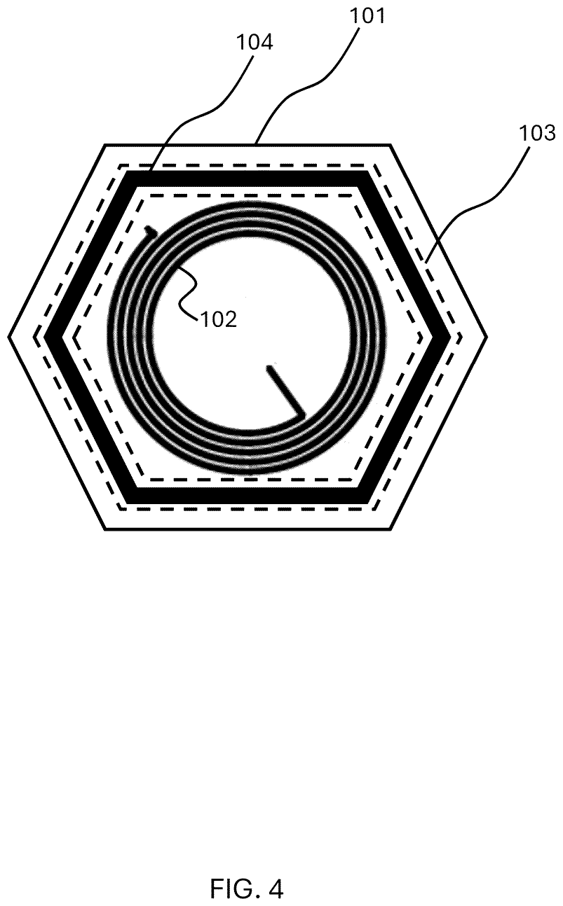

FIG. 4 shows a further exemplary, non-limiting implementation with a schematic representation of the third exemplary, non-limiting implementation of the coil board 101.

The recess 103 is polygonal. Optionally, a polygonal recess 103, in FIG. 4 specifically a hexagonal recess, is formed.

The recess 103 runs around the coil element 102, which is circular and spiral-shaped.

The shielding element 104 is placed in this hexagonal recess 103 and, like the recess 103, is likewise polygonal. Optionally, a polygonal form, in FIG. 4 specifically a hexagonal form, of the shielding element 104 is shown. The shielding element serves for the electromagnetic shielding of the coil element 102.

The polygonal form of the shielding element 104 permits stable positioning in the recess 103 and offers uniform shielding.

This exemplary, non-limiting implementation illustrates that other polygonal forms of the shielding element 104, such as, for example, pentagonal or polygonal forms, are likewise possible. This is shown in FIG. 4, for example, by means of a hexagonal design.

FIG. 5 shows a further exemplary, non-limiting implementation with a schematic representation of the fourth exemplary, non-limiting implementation of the coil board 101.

The coil board 101 comprises a coil element 102, which is diamond- and spiral-shaped.

In other exemplary, non-limiting implementations, the diamond-shaped coil element 102 can be used, for example, instead of or in combination with the circular and spiral-shaped coil element 102, so that the recess 103 and the shielding element 104 surround the coil element 102 in any desired closed and encircling form.

The recess 103 is circular.

In this circular recess 103 there is arranged a shielding element 104, which likewise has a circular configuration.

This circular design is, for example, a specific form of an annular structure.

The circular construction of the shielding element 104 offers a uniform shielding effect around the coil element 102, since electromagnetic interference from all directions is effectively reduced by the continuous form. This leads to improved stability and sensitivity of the sensor, since there are no unprotected regions and the electromagnetic shielding is optimized.

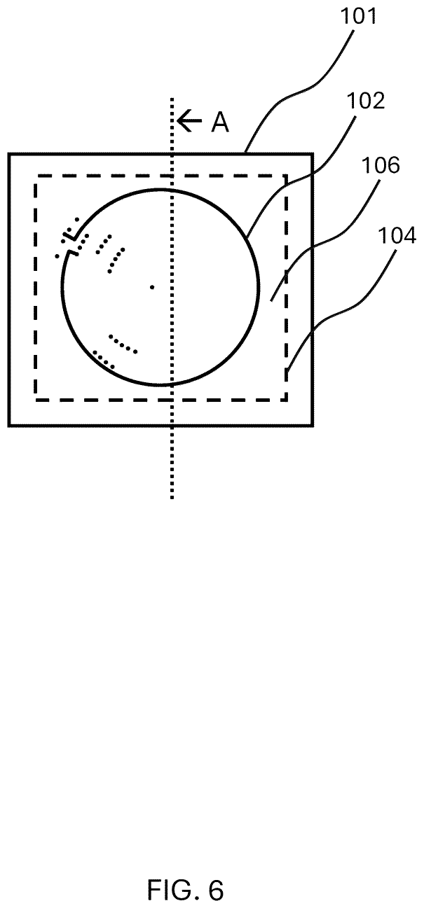

FIG. 6 shows a schematic representation of an individual layer of the first exemplary, non-limiting implementation of the coil board with a section axis A.

In FIG. 6, a layer 106 of the coil board is shown by way of example.

There is further shown a detail of a coil board 101 with a rectangular shielding element 104, shown schematically, which encloses the coil element 102.

The coil element 102 is arranged in a layer 106 of the coil board 101.

The shielding element 104 with the recess 103 is arranged in the same layer and ensures direct shielding of the coil element 102.

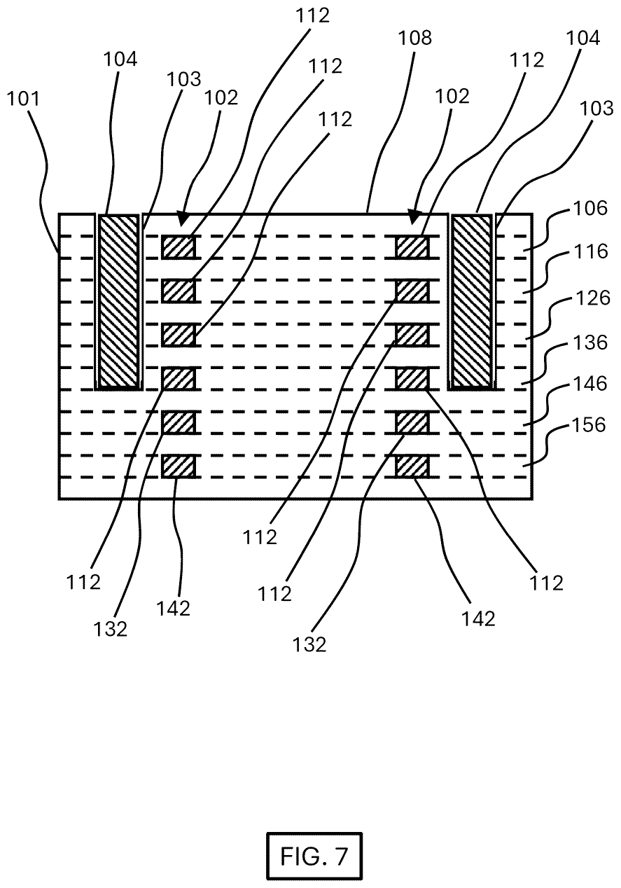

FIG. 7 shows the schematic representation of a cross section along the section axis A from FIG. 6. This is, by way of example, the coil board 101 of the first exemplary, non-limiting implementation. Any desired other exemplary, non-limiting implementation of the description can be represented along the section axis A.

In this representation, a further exemplary, non-limiting implementation of the coil board 101 with a coil element 102 and windings 112 is shown, which is formed at least in one of the layers 106, 116, 126, 136 of the coil board 101.

As shown in FIG. 6, one layer of the coil element 102 is circular, and for this reason the cross section of the coil board 101 is symmetrical in the representation of FIG. 7.

The coil element 102 is symmetrical and in each case shows two details of the windings 112 of the coil element 102.

The shielding element 104 and the recess 103 are likewise symmetrical.

The coil board 101 consists of multiple layers, including the copper layers 106, 116, 126, 136, 146, 156 in which the electrically conducting windings 112 of the coil element 102 are formed. These copper layers can also contain the conductive material that forms the windings of further coil elements 132, 142.

The windings of the further coil elements 132, 142 can also be configured as windings 112 of the same coil element 102, so that the shielding element 104 is arranged in the recess 103 at the height of the windings 112 in the layers 106, 116, 126, 136 and the windings 132, 142 are not surrounded by the recess 103 and the shielding element 104.

The layers between the layers 106, 116, 126, 136, 146, 156 can serve, for example, as insulation layers. Additional conductive regions for contacting the windings and further elements can be arranged in these insulation layers.

This multi-layer arrangement permits a compact construction without impairing the electromagnetic shielding effect of the shielding element 104 in the recess 103.

The coil element 102 is of multi-layer form and comprises at least two coil layers, optionally the four coil windings 112 in the layers 106, 116, 126, 136.

The shielding element 104 and the recess 103 are formed parallel to the coil element 102. As is shown more precisely in FIG. 7, the shielding element 104 is arranged parallel to at least one layer 106, 116, 126, 136 of the coil element 102, or of the coil board 101. This means that the recess 103 is configured as a moat, encircling and closed around the coil element 102. The recess 103 thus runs through the multi-layer structure of the coil board 101 and the multi-layer construction of the coil element 102. The shielding element 104 is accordingly so arranged that it lies at least in a plane that corresponds to at least one plane of the layers 106, 116, 126, 136 of the coil board and thus is arranged parallel to this or further layers 146, 156. The shielding element 104 is thus formed parallel to the coil element 102.

Depending on the design, i.e. thickness or height, of the shielding element 104 and on the depth of the recess 103, the shielding element 104 can extend over multiple layers 106, 116, 126, 136 of the coil board 101, whereby it permits precise shielding of the windings 112 in the layers 106, 116, 126, 136 of the coil board 101.

The shielding element 104 thus ensures electromagnetic shielding that is matched directly to the coil element 102, whereby the effectiveness of the electromagnetic shielding of the coil board 101 is optimized and maximized.

Optionally, the shielding element 104 and the recess 103 are configured such that they are formed over multiple layers 106, 116, 126, 136.

The multi-layer coil 102 with the coil windings 112 in the layers 106, 116, 126, 136 is enclosed by the shielding element 104 and by the recess 103.

The layers 146, 156 with the further coil elements 132, 142 are not covered by the shielding element 104 and the recess 103.

The further coil elements 132, 142 can also be, for example, windings of a further coil element.

The multi-layer coil 102 with the windings 112 and the coil elements 132, 142 can in each case be, for example, transmitting and/or receiving coils.

This configuration shows how the shielding element 104 can be positioned precisely relative to the multi-layer coil element 102 with the windings 112, which ensures optimal electromagnetic shielding without increasing the space requirement.

The multi-layer arrangement of the coil element 102 improves the sensitivity and electromagnetic performance of the sensor, for example of the inductive proximity sensor, while the shielding element 104 is integrated precisely across multiple layers 106, 116, 126, 136 of the coil board 101.

In a further exemplary, non-limiting implementation, which is not shown in the FIGS., the shielding element 104 and the recess 103 can also be formed into the deeper layers 146, 156.

In addition, in a further exemplary, non-limiting implementation (not shown), the recess 103 can be deeper than the shielding element 104 is high. This means that the recess 103 is formed, for example, from the surface 108 of the coil board 101 deep into the layer 156, wherein the shielding element 104 is formed only from layer 126 to layer 156.

The coil board in FIG. 1 to 7 is designed as an inductive proximity sensor which is able to be flush mounted, especially as an inductive proximity sensor which is able to be flush mounted in a metallic environment, in which shielding of the coil element 102 by the shielding element 104 takes place in the height of the coil element 102. The maximum spread of the electromagnetic field is thus utilized optimally, which leads to highest switching distances.

In addition, the coil element 102 can take various forms, for example spiral-shaped in combination with circular and diamond-shaped configurations. The positioning of the shielding element 104 in the recess 103 of the coil board 101 permits direct and precise fixing during assembly.

The recess 103 is formed in the exemplary, non-limiting implementations by milling or depth milling.

This represents an important advantage in the joining technique of this device. Novel joining techniques and methods, such as the insertion of the shielding element during population of the board as well as fixing of the shielding element by soldering after positioning in a front cap of the sensor, additionally contribute toward improved production accuracy and stability.

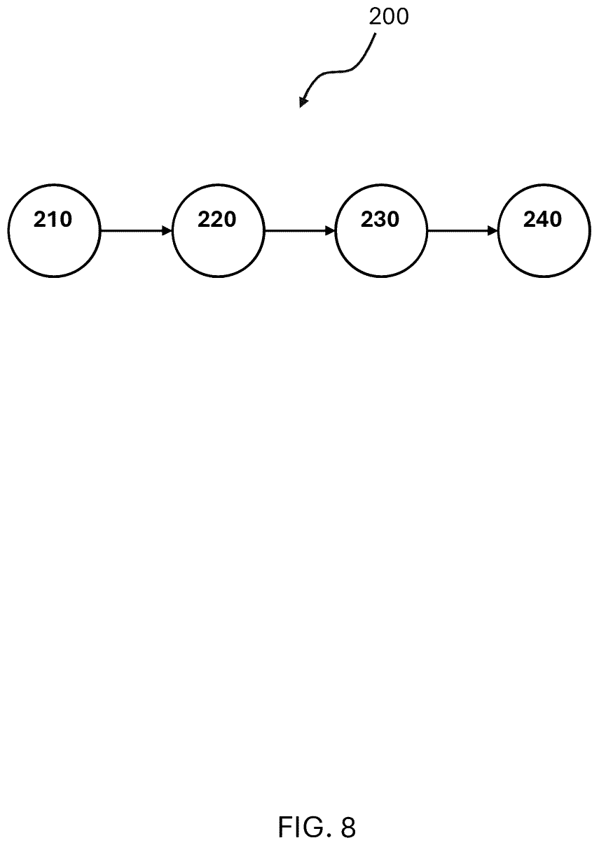

FIG. 8 shows a flow diagram of a method according to the disclosure.

Optionally, a schematic overview of the entire process of manufacturing the coil board 101 is shown. The process that is shown begins with step 210, provision of the coil board 101 with the coil element 102. In the next step 220, an encircling and closed recess 103 is formed in the coil board 101. Step 230 shows the arrangement of the shielding element 104 in the recess 103.

In step 240, the shielding element 104 is fixed in the recess 103, in order to ensure stable and reliable positioning, for example by soldering. This schematic sequence represents an efficient and precise method for producing the coil board by novel joining techniques and methods, such as insertion of the shielding element during population and fixing of the coil board, and additionally contribute toward improved production accuracy and stability.

### Reference Symbols

101 Coil board
102 Coil element
103 Recess
104 Shielding element
105 insulating carrier material
106, 116, 126, 136, 146, 156 Layer
108 Surface
112 Windings
132, 142 Further coil elements
200 Method for production
210 to 240 Method steps

What is claimed is:

1. A coil board, comprising:
an insulating carrier material;
at least one coil element formed on top of or at least partly inside the insulating carrier material;
a recess that is formed in an encircling and closed manner around the coil element, wherein the recess is embedded in the insulating carrier material; and
a separate, preformed shielding element, wherein the shielding element is arranged precision-fitted in the recess of the coil board.

2. The coil board according to claim 1, wherein the coil board is designed for an inductive proximity switch.

3. The coil board according to claim 2, wherein the inductive proximity switch is designed for flush mounting in a metallic environment.

4. The coil board according to claim 1, wherein the shielding element is formed of a conductive material.

5. The coil board according to claim 4, wherein the conductive material includes brass or copper.

6. The coil board according to claim 1, wherein the shielding element has a closed form.

7. The coil board according to claim 1, wherein the shielding element has an annular form.

8. The coil board according to claim 6, wherein the recess and the shielding element have a same closed form, so that the form of the shielding element corresponds to the form of the recess.

9. The coil board according to claim 6, wherein the shielding element is circular.

10. The coil board according to claim 6, wherein the shielding element is polygonal.

11. The coil board according to claim 10, wherein the shielding element is polygonal with rounded corners.

12. The coil board according to claim 1, wherein the coil element is formed in at least one layer of the coil board and the shielding element is arranged in at least that layer.

13. The coil board according to claim 1, wherein an areal extent of the coil element corresponds to 70-90% of an areal extent of the shielding element.

14. A method for producing the coil board according to claim 1, comprising:
providing the coil board including the insulating carrier material and the at least one coil element formed on top of or at least partly inside the insulating carrier material;
forming the recess in the insulating carrier material, wherein the recess is formed in the encircling and closed manner around the coil element and wherein the recess is embedded in the insulating carrier material; and
arranging the separate, preformed shielding element in the recess of the coil board.

15. The method according to claim 14, further comprising fixing the shielding element in the recess.

16. The method according to claim 15, further comprising fixing the shielding element in the recess by soldering.

17. A method, comprising using the coil board according to claim 1 in an inductive proximity switch.

18. The method according to claim 17, wherein the inductive proximity switch is designed for flush mounting in a metallic environment.
